(19) United States
(12) Patent Application Publication
(10) Pub. No.: US 2013/0118555 A1
(43) Pub. Date: May 16, 2013

(54) SOLAR ENERGY COLLECTORS AND METHODS FOR CAPTURING SOLAR ENERGY

(71) Applicant: Nebula Energy Inc., East Hartford, CT (US)

(72) Inventor: Davian A. Samuels, East Hartford, CT (US)

(73) Assignee: NEBULA ENERGY INC., East Hartford, CT (US)

(21) Appl. No.: 13/676,068

(22) Filed: Nov. 13, 2012

Related U.S. Application Data
(60) Provisional application No. 61/559,064, filed on Nov. 12, 2011.

(51) Int. Cl. H01L 31/058; H01L 31/052

(52) U.S. Cl. CPC H01L 31/058; H01L 31/0522
USPC 136/248; 136/246

(57) ABSTRACT

A solar energy collector or tower adapted to position photovoltaic devices in urban and suburban settings is provided. The tower includes an elongated pole, a plurality of photovoltaic modules pivotally mounted to the pole at a plurality of elevations, wherein each of the plurality of modules includes a housing, and a plurality of photovoltaic devices mounted in the housing; a drive mechanism adapted to rotate each of the pivotally mounted photovoltaic modules; and a base assembly adapted to pivotally support the pole. The tower and modules are designed to minimize wind load. The photovoltaic modules include a solar energy heat exchanger having a plurality of photovoltaic devices mounted with a plurality of reflective surfaces positioned to concentrate solar energy upon the photovoltaic devices. The photovoltaic devices and reflective surfaces may be positioned on panels or pyramidal structures. Methods and devices for collecting solar energy are also included.

### CROSS-REFERENCE TO RELATED APPLICATIONS

This application claims priority from pending U.S. Provisional Patent Application 61/559,064 filed on Nov. 12, 2011, the disclosure of which is included by reference herein in its entirety.

### BACKGROUND OF THE INVENTION

1. Technical Field

The present invention generally relates to the capturing of solar energy and the conversion of that solar energy to electricity and heat. More particularly, the present invention relates to systems, devices, and methods for enhancing the collection of solar energy with photovoltaic device mounted on articulating structures.

2. Description of Related Art

In the early twenty-first century the cost of energy continues to climb while non-renewable resources continue to be consumed. As a consequence, interest in renewable resources, such as, wind and solar, not only provide a potential solution but can provide one basis for economic opportunity. Solar energy generated photovoltaic (PV) devices is an area receiving marked interest in investment and development. While the cost of PV devices decreases the implementation of PV devices continues to rise.

It is well recognized that one of the disadvantages of PV devices is the amount of real estate required for such installations. Due to the simple relationship of exposing as much PV devices to solar radiation, large, expansive solar cell installations having relatively large footprints are typically the norm. Accordingly, based on the present state of the technology, the installation of photovoltaic devices are typically limited to areas having available real estate and are not as in areas with limited real estate, for example, in urban or suburban areas.

In addition, the appearance of the present state of PV installation technology is does not lend itself to urban and suburban areas. The often expansive and unwieldy appearance of conventional PV installations further detracts from their acceptance in populated areas.

Moreover, existing PV systems typically are divorced from solar hot water systems. Though based upon the same source of energy, that is, solar radiation, existing energy collection systems typically embody only solar-to-electrical energy capture and only solar-to-hot water energy capture.

The present invention addresses the limitations of present PV installations or concentrated photovoltaic (CPV) installations.

### SUMMARY OF THE INVENTION

The present invention, in its several embodiments and many aspects, overcomes the limitations and disadvantages of the prior art. Aspect of the present invention provide PV devices mounted in vertical assemblies, for example, in “tree-like” structures, that can be installed at ground level or on roof tops that minimize the installation footprint. These installations include PV or CPV modules that enhance the capture of solar radiation while also providing a source of heated, for example, water. In addition, the aspects of the present invention provide aesthetically acceptable appearances while minimizing wind loading.

One embodiment of the invention is a solar energy collector comprising or including an elongated pole; a plurality of photovoltaic modules pivotally mounted to the pole at a plurality of elevations, wherein each of the plurality of modules comprises: a housing; and a plurality of photovoltaic devices mounted in the housing; a drive mechanism adapted to rotate each of the pivotally mounted photovoltaic modules; and a base assembly adapted to support the pole. In one aspect, each of the plurality of photovoltaic modules includes a photovoltaic energy heat exchanger mounted in the housing comprising a plurality of elongated, thermally conductive panels, wherein the plurality of photovoltaic devices mounted in the housing comprise a plurality of photovoltaic devices mounted to and in thermal communication with at least some of the plurality of thermally conductive panels; a plurality of reflective surfaces positioned to reflect sunlight on the plurality of photovoltaic devices; and a cooling fluid conduit in thermal communication with at least some of the plurality elongated, thermally conductive panels.

In another aspect, each of the plurality of photovoltaic modules further comprises or includes a photovoltaic energy heat exchanger mounted in the housing having a plurality of pyramidal structures, wherein the plurality of photovoltaic devices mounted in the housing comprise a plurality of photovoltaic devices mounted to and in thermal communication with at least one face of each of the plurality of the pyramidal structures; a plurality of reflective surfaces, each of the plurality of reflective surfaces positioned on at least one face of each of the plurality of the pyramidal structures, the plurality of reflective surfaces positioned to reflect sunlight on the plurality of photovoltaic devices; and a cooling fluid conduit in thermal communication with at least some of the plurality of pyramidal structures. The plurality of pyramidal structures may be pyramidal recesses or pyramidal projections.

Another embodiment of the invention is a method for collecting solar energy comprising or including pivotally mounting a plurality of photovoltaic modules to a pole at a plurality of elevations, wherein each of the plurality of modules comprises: a housing; and a plurality of photovoltaic devices mounted in the housing and adapted to receive solar energy and convert the solar energy to electrical energy; pivoting each of the plurality of photovoltaic modules about an axis to vary the amount of solar energy received by the plurality of photovoltaic devices; and supporting the pole in a base assembly. In one aspect, the method may further include rotating the pole about the base to further vary the amount of solar energy received by the photovoltaic devices. In another aspect, the method may include pivoting the pole about the base to further vary the amount of solar energy received by the photovoltaic devices. In a further aspect, the plurality of photovoltaic devices may generate thermal energy, and wherein the method may further include conducting the thermal energy away from the plurality of photovoltaic devices by passing a cooling fluid in thermal communication with the plurality of photovoltaic devices. The cooling fluid may be a liquid or a gas.

In another aspect, pivotally mounting the plurality of photovoltaic modules to the pole at the plurality of elevations may be practiced by mounting the plurality of photovoltaic modules to the pole with a separation between the photovoltaic modules along the pole that minimizes obstruction of solar radiation on the plurality of photovoltaic device in the plurality of photovoltaic modules.

Another embodiment of the invention is a solar energy heat exchanger comprising or including a first elongated, thermally conductive panel and a second elongated, thermally conductive panel, wherein a plane of the first elongated panel forms an angle, θ, with a plane of the second elongated panel; a plurality of photovoltaic devices adapted to receive solar energy and convert the solar energy to electrical energy, the plurality of photovoltaic devices mounted to and in thermal communication with at least one of the first elongated panel and the second elongated panel; a plurality of thermally conductive ribs mounted beneath at least one of the first elongated panel and the second elongated panel, the plurality of conductive ribs in thermal communication with at least one of the first elongated panel and the second elongated panel; a plurality of reflective surfaces positioned to reflect sunlight on the plurality of photovoltaic devices; and a cooling fluid conduit in thermal communication with at least some of the plurality of thermally conductive ribs. In one aspect, the first panel and the second panel may be an elongated plate bent at the angle, θ, for example, bent at between 80 and 100 degrees. In one aspect, the plurality of photovoltaic devices is mounted to and in thermal communication with the first elongated panel and the second elongated panel.

Another embodiment of the invention is a solar concentrator and heat exchanger comprising or including a housing; a plurality of first elongated, thermally conductive panels mounted in the housing, each of the plurality of first elongated panels defining a plane; a plurality of photovoltaic devices adapted to receive solar energy and convert the solar energy to electrical energy, the plurality of photovoltaic devices mounted to and in thermal communication with at least some of the plurality of elongated first panels; a plurality of reflective surfaces positioned to reflect sunlight on the plurality of photovoltaic devices, each of the plurality of reflective surfaces positioned on a plane making an angle, θ, with the plane of at least one of the plurality of first elongated panels; and a plurality of cooling fluid conduits in thermal communication with at least some of the plurality of first elongated, thermally conductive panels. In one aspect, the solar concentrator and heat exchanger further comprises a plurality of second elongated, thermally conductive panels mounted in the housing, each of the plurality of second elongated panels defining a plane; and wherein the plurality of photovoltaic devices mounted in the housing comprises a plurality of first photovoltaic devices, and wherein the solar concentrator and heat exchanger further comprises a plurality of second photovoltaic devices mounted to and in thermal communication with the plurality of second thermally conductive panels. In another aspect, the plurality of cooling fluid conduits may be a plurality of fluid cooling conduits in thermal communication with at least some of the plurality of first panels and at least some of the plurality of second panels, for example, via at least some thermally conductive ribs. In another aspect, the solar concentrator and heat exchanger may a plurality of reflective surfaces positioned on at least some of the plurality of first panels positioned to reflect sunlight on the plurality of photovoltaic devices mounted to at least some of the plurality of first panels.

A further embodiment of the invention is a method for collecting solar energy comprising or including exposing a plurality of photovoltaic devices adapted to receive solar energy and convert the solar energy to electrical energy to sunlight, the plurality of photovoltaic devices mounted on a thermally conductive substrate; reflecting sunlight from a plurality of reflective surfaces on to the plurality of photovoltaic devices; allowing the thermally conductive substrate to absorb thermal energy from the sunlight; passing a cooling fluid in thermal communication with at least some of the thermally conductive substrate to transfer thermal energy from the substrate to the cooling fluid. In one aspect, the plurality of photovoltaic devices comprises a first plurality of photovoltaic devices and the thermally conductive substrate comprises a first thermally conductive panel, wherein the method further comprises exposing a second plurality of photovoltaic devices adapted to receive solar energy and convert the solar energy to electrical energy to sunlight, the plurality of second photovoltaic devices mounted on a second thermally conductive panel.

A still further embodiment of the invention is a photovoltaic panel comprising or including a plurality of pyramidal structures; a plurality of photovoltaic devices mounted to at least one face of each of the plurality of the pyramidal structures; and a plurality of reflective surfaces, each of the plurality of reflective surfaces positioned on at least one face of each of the plurality of the pyramidal structures, the plurality of reflective surfaces positioned to reflect sunlight on the plurality of photovoltaic devices. The plurality of pyramidal structures may be a plurality of pyramidal recesses, a plurality of pyramidal projections, or a combination thereof. In one aspect, each of the plurality of pyramidal structures may have at least three sides and a base. In another aspect, each of the plurality of pyramidal structures consists of only three sides, no more, no less, and a base.

In another aspect, the plurality of pyramidal structures may be a first plurality of pyramidal structures, and wherein the panel may further comprise a second plurality of pyramidal structures, smaller than the first plurality of pyramidal structures, positioned on at least one face of each of the first plurality of pyramidal structures. In another aspect, the panel may further include a third plurality of pyramidal structures, smaller than the second plurality of pyramidal structures, positioned on at least one face of each of the second plurality of pyramidal structures.

A still further embodiment of the invention is a solar energy heat exchanger comprising or including a plurality of pyramidal structures; a plurality of photovoltaic devices mounted to and in thermal communication with at least one face of each of the plurality of the pyramidal structures; a plurality of reflective surfaces, each of the plurality of reflective surfaces positioned on at least one face of each of the plurality of the pyramidal structures, the plurality of reflective surfaces positioned to reflect sunlight on the plurality of photovoltaic devices; and a cooling fluid conduit in thermal communication with at least some of the plurality of pyramidal structures. In one aspect, the plurality of pyramidal structures may be a plurality of pyramidal recesses, a plurality of pyramidal projections, or a combination thereof. In one aspect, the each of the plurality of pyramidal structures has at least three sides and a base.

These and other aspects, features, and advantages of this invention will become apparent from the following detailed description of the various aspects of the invention taken in conjunction with the accompanying drawings.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention will be readily understood from the following detailed description of aspects of the invention taken in conjunction with the accompanying drawings in which:

FIG. 1 is a perspective view of a photovoltaic tower assembly according to one aspect of the invention.

FIG. 2 is a front elevation view of the photovoltaic tower assembly shown in FIG. 1.

FIG. 3 is a rear elevation view of the photovoltaic tower assembly shown in FIG. 1.

FIG. 4 is a right-side elevation view of the photovoltaic tower assembly shown in FIG. 1, the left-side elevation view being substantially a mirror image thereof.

FIG. 5 is a top plan view of the photovoltaic tower assembly shown in FIG. 1.

FIG. 6 is a front perspective of a photovoltaic module shown in FIGS. 1 through 5 according to one aspect of the invention.

FIG. 7 is a rear perspective view of the photovoltaic module shown in FIG. 6.

FIG. 8 is a front view of the photovoltaic module shown in FIG. 6.

FIG. 9 is a right side view of the photovoltaic module shown in FIG. 6, the left-side view being substantially a mirror image thereof.

FIG. 10 is an exploded perspective view of the photovoltaic module shown in FIG. 6.

FIG. 11 is a perspective view of the solar concentrator and heat exchanger assembly shown in FIG. 10.

FIG. 12 is a front view of the solar concentrator and heat exchanger assembly shown in FIG. 11.

FIG. 13 is a rear view of the solar concentrator and heat exchanger assembly shown in FIG. 11.

FIG. 14 is a cross sectional view of solar concentrator and heat exchanger shown in FIG. 12 as viewed along section lines 14-14 shown in FIG. 12.

FIG. 15 is a detailed perspective view of the solar concentrator and heat exchanger assembly, partially in cross section, shown in FIG. 11 as identified by Detail 15 shown in FIG. 11.

FIG. 16 is a detailed perspective view of a portion of the solar concentrator and heat exchanger assembly shown in FIG. 11, similar to FIG. 15, according to another aspect of the invention.

FIG. 17 is a detailed perspective view of the portion of the solar concentrator and heat exchanger assembly, partially in cross section, shown in FIG. 16 as viewed along section lines 17-17 shown in FIG. 16.

FIG. 18 is a plan view of solar energy concentrating “cell” according to another aspect of the invention.

FIG. 19 is a plan view of the solar energy-concentrating cell shown in FIG. 18 illustrating typical pathways of solar radiation according to an aspect of the invention.

FIG. 20 is a perspective view of the solar energy concentrating cell shown in FIG. 19 with the typical pathways of solar radiation shown in FIG. 19.

FIG. 21 is a plan view of one arrangement of a plurality of the solar energy concentrating cells shown in FIGS. 18 through 20 according to one aspect of the invention.

FIG. 22 is a plan view of another arrangement of a plurality of the solar energy concentrating cells shown in FIGS. 18 through 20 according to another aspect of the invention.

FIG. 23 is a top perspective view of the light assembly of the photovoltaic tower shown in FIG. 1 according to one aspect of the invention.

FIG. 24 is a bottom perspective view of the light assembly shown in FIG. 23.

FIG. 25 is an exploded top perspective view of the light assembly shown in FIGS. 23 and 24.

FIG. 26 is a perspective view of a photovoltaic module mounting and drive assembly for the tower shaft shown in FIG. 1.

FIG. 27 is an exploded perspective view of a photovoltaic module mounting and drive assembly shown in FIG. 26.

FIG. 28 is an elevation view, with cover removed, of the base assembly of the tower assembly shown in FIG. 1.

FIG. 29 is an elevation view the tower assembly shown in FIG. 1 as tilted to enhance solar energy captures according to one aspect of the invention.

### DETAILED DESCRIPTION OF THE INVENTION

The present invention, in its several embodiments and numerous aspects, provides systems, devices, and methods for enhancing the capture of solar energy and the conversion of the solar energy to electrical energy and/or hot water. In addition to these benefits, aspect of the invention provide aesthetically pleasing installations that are more likely to be acceptable in urban and suburban communities.

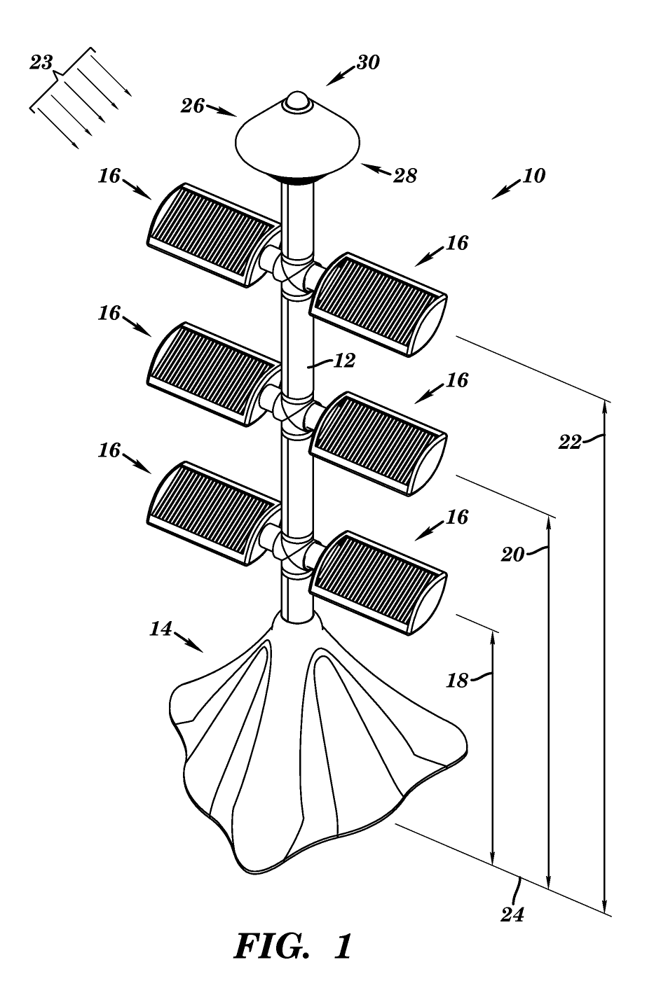

FIG. 1 is a perspective view of a photovoltaic tower assembly or solar energy collector 10 according to one aspect of the invention. As shown, tower assembly 10 may typically include an elongated pole, shaft, or column 12 mounted in a base assembly 14 adapted to support the pole 12 and a plurality of photovoltaic modules 16. Modules 16 may be pivotally mounted to the pole 12 at a plurality of elevations 18, 20, 22, for example, from a datum or a ground level 24. The height of tower 10 may vary depending upon the parameters of the installation; however, the height of tower 10 may vary from about 10 feet to about 100 feet, but typically is between about 20 feet and about 40 feet.

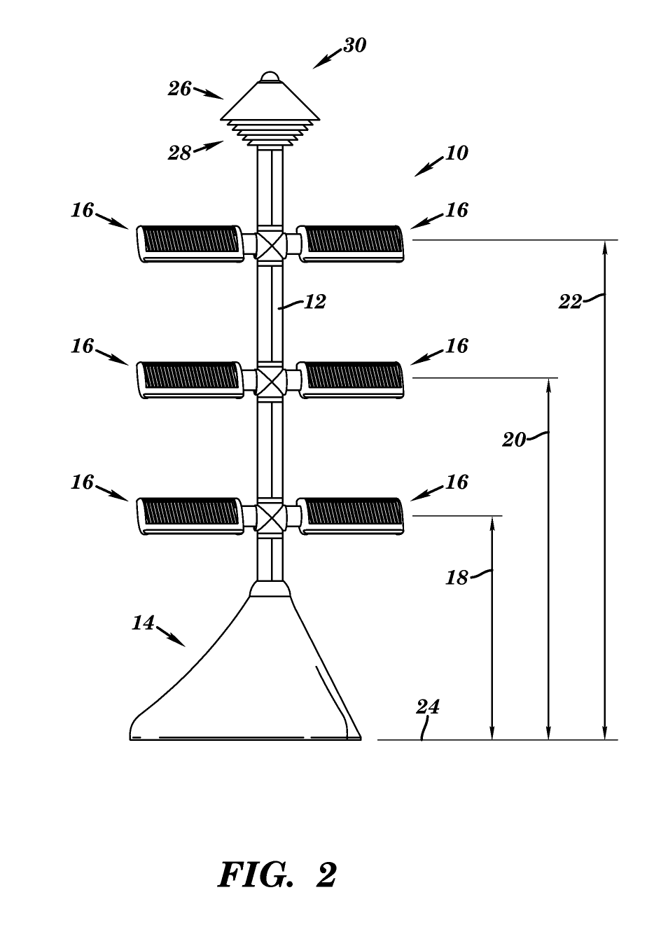

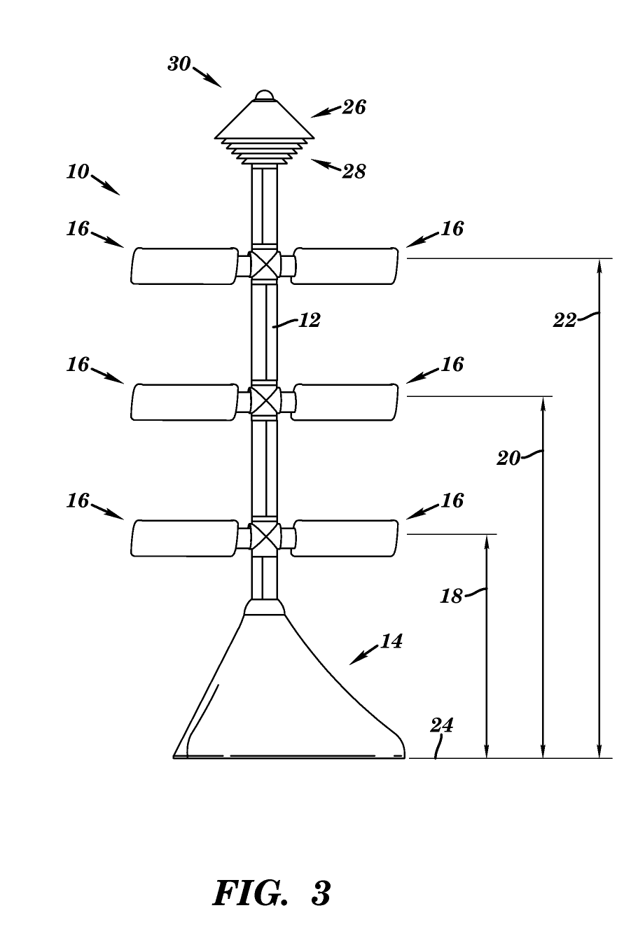

According to aspects of the invention, photovoltaic modules 16 typically include a plurality of photovoltaic (PV) devices, for example, any conventional solar cells, and the like, that is, devices adapted to convert incident solar radiation, as indicated schematically by arrows 23, to electrical energy. FIG. 2 is a front elevation view of the photovoltaic tower assembly or solar energy collector 10 shown in FIG. 1. FIG. 3 is a rear elevation view of the photovoltaic tower assembly or solar energy collector 10 shown in FIG. 1.

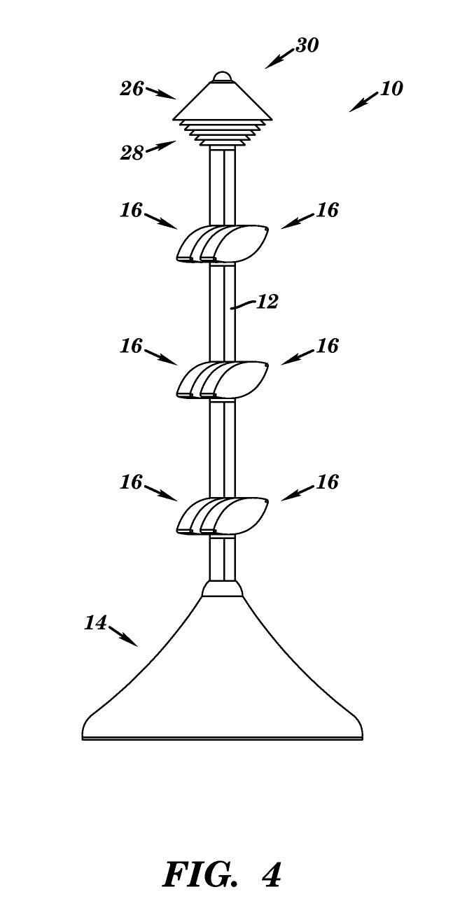

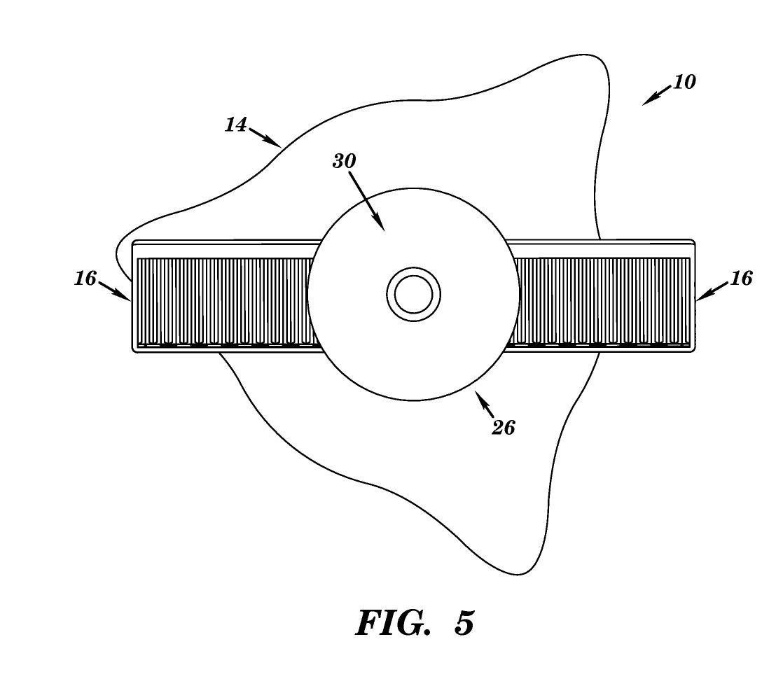

FIG. 4 is a right-side elevation view of the concentrated photovoltaic tower assembly or solar energy collector 10 shown in FIG. 1, the left-side elevation view being substantially a mirror image thereof. FIG. 5 is a top plan view of the photovoltaic tower assembly or solar energy collector 10 shown in FIG. 1.

In one aspect, the tower assembly 10 shown in FIGS. 1 through 5 may be referred to as a concentrating photovoltaic (or CPV) tower assembly. In one aspect, Nebula Energy Inc. of East Hartford, Conn. markets the photovoltaic tower assembly or solar energy collector 10 shown in FIGS. 1 through 5 under the name “SolarzTree™ System”.

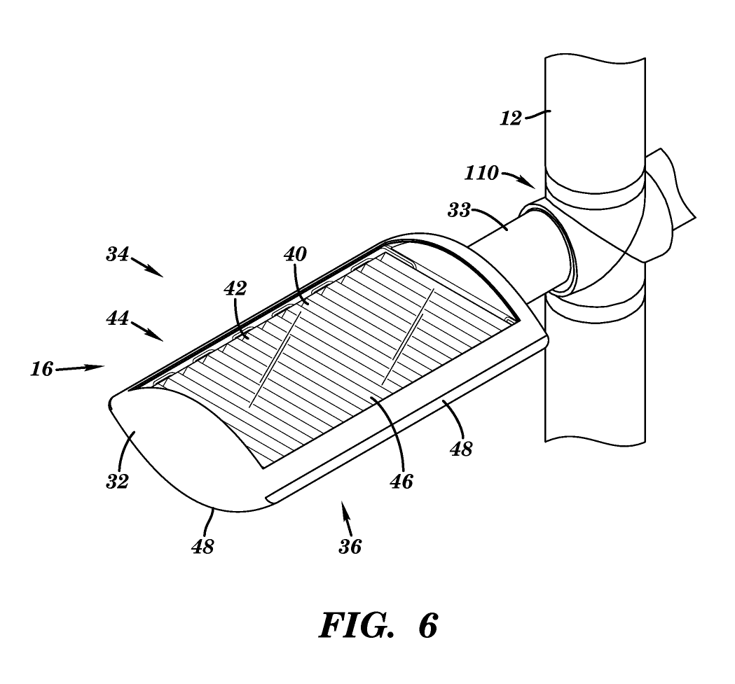

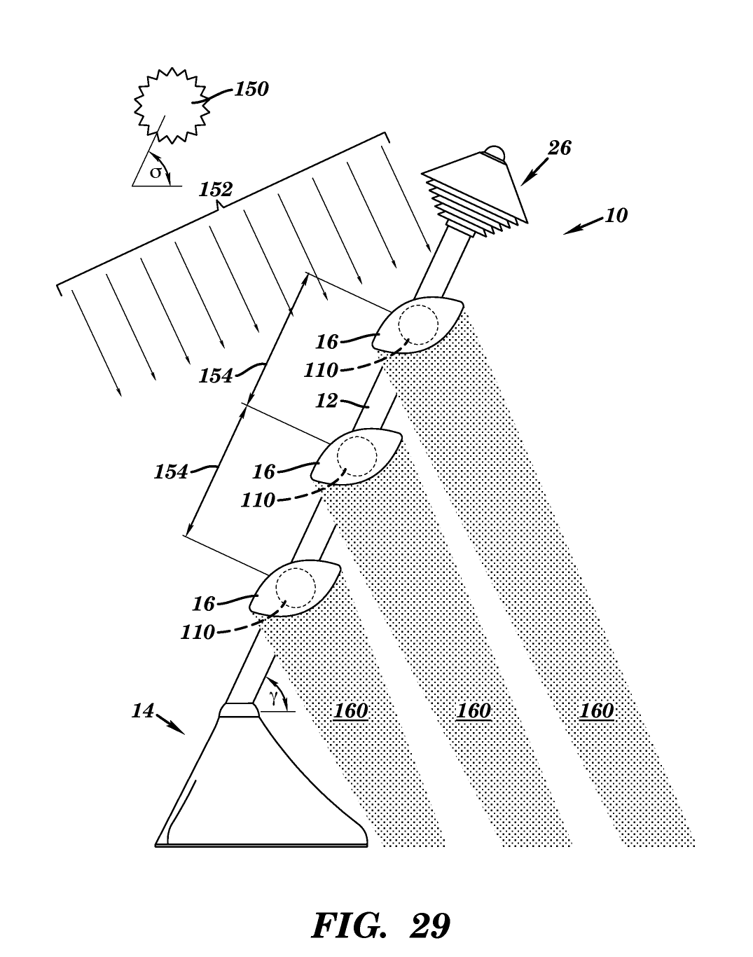

In the aspect of the invention shown in FIGS. 1 through 5, tower assembly or collector 10 includes six (6) photovoltaic (PV) modules 16, for example, PV modules 16 pivotally mounted to pole 12, that is, adapted to rotate about an axis. However, aspects of the invention may include 1 or more modules 16, for example, 2 or more, 3 or more, or 8 or more, or 10 or more modules 16. The details of modules 16 are shown and described below with respect to FIGS. 6 through 22. Though not shown in FIGS. 1 through 5, in one aspect, tower assembly or collector 10 may include a drive mechanism adapted to rotate each of the pivotally mounted PV modules 16, for example, about a horizontal axis. Accordingly, aspects of the invention may include the capability to rotate one or more of the PV modules 16 to vary or optimize the orientation of the PV modules 16 to, for example, enhance the solar energy collecting capacity of the collector 10 as the elevation of the sun vary during the day or throughout the year. In addition, as will be discussed more completely with respect to FIG. 29 below, according to another aspect of the invention, collector 10 may also be adapted to vary the orientation of pole 12, for example, with respect to base assembly 14 in order to further enhance the solar energy collecting capability of collector 10 as the elevation of the sun varies during the day or throughout the year. For instance, the base assembly 14 may be adapted to pivotally and rotationally support pole 12 whereby the orientation of PV modules 16 may be varied.

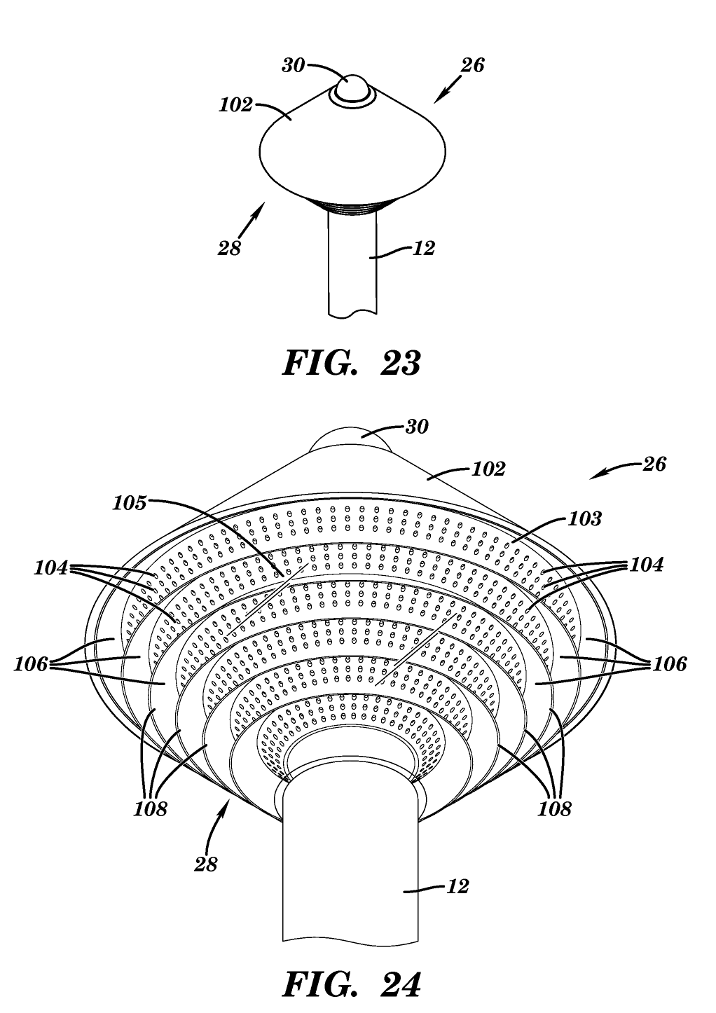

As also shown in FIGS. 1 through 5, tower or collector 10 may also include a light assembly 26 mounted to pole 12, for example, to the top of pole 12. As shown and described more completely with respect to FIGS. 23 through 25 below, light assembly 26 may include a plurality of light sources 28, for example, LED light sources, and may be powered by the solar energy captured by one or more PV modules 16. Light assembly 26 may also include one or more detectors or cameras 30, for example, a detector adapted to detect the amount of sunlight available or a security camera adapted to detect images of the area about the collector 10, for example, in an adjacent playground, park, parking lot or parking garage.

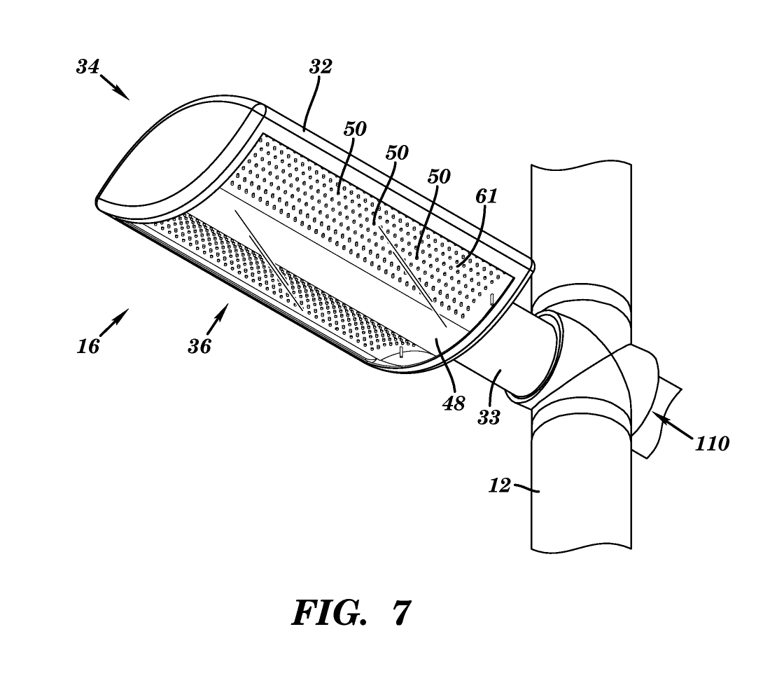

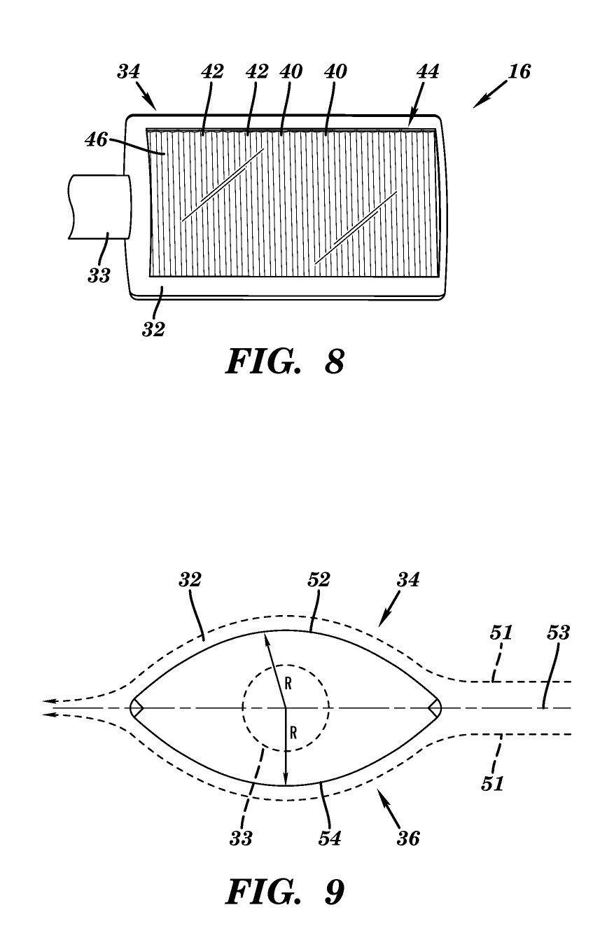

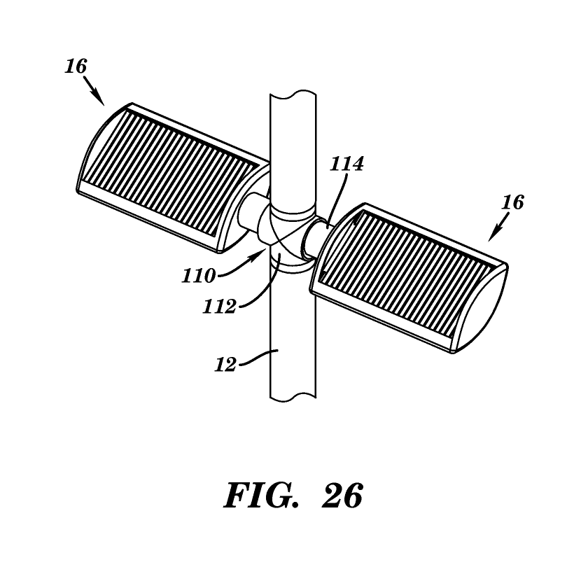

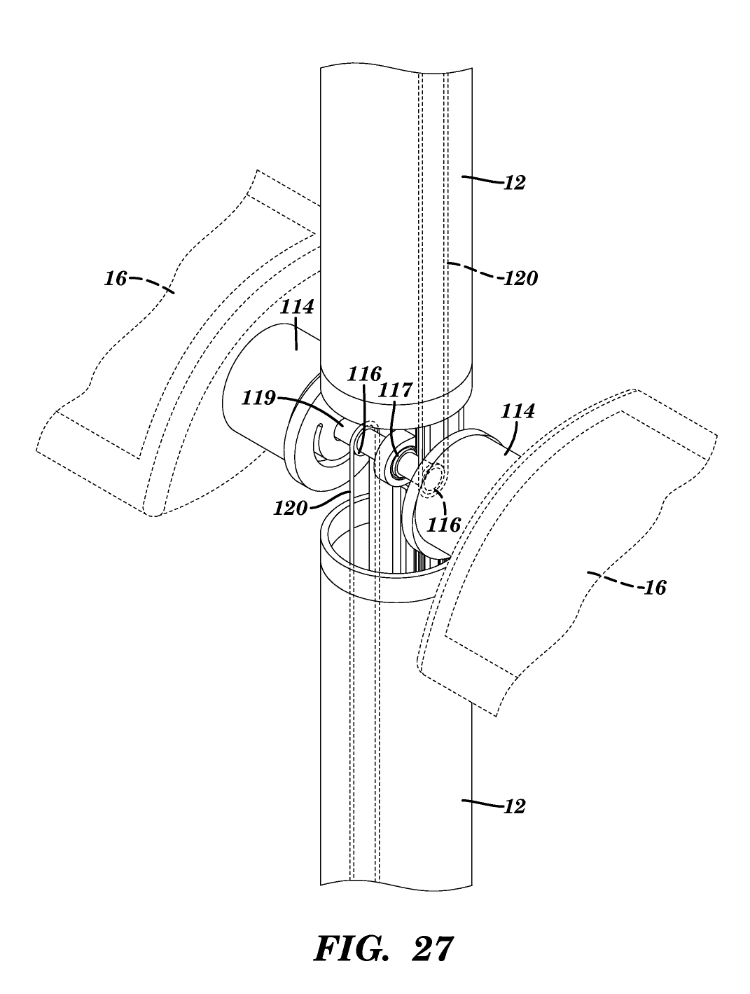

FIG. 6 is a front perspective view of a photovoltaic (PV) module 16 shown in FIGS. 1 through 5 according to one aspect of the invention. FIG. 6 includes a represented portion of pole 12 and a portion of module mounting and drive mechanism 110 (see FIGS. 26 and 27) by which module 16 may be mounted to pole 12 and rotated. FIG. 7 is a rear perspective view of the PV module 16 and FIG. 8 is a front view of the PV module 16 shown in FIG. 6. FIG. 9 is a right side view of the PV module shown in FIG. 6, the left-side view of PV module 16 being substantially a mirror image thereof.

As shown in FIGS. 6 through 9, PV module 16 includes a housing 32 having a front housing portion 34 and a rear housing portion 36. Housing 32 may be mounted to the module mounting and drive mechanism 110 by mean of a shaft 33, for example, by conventional mounting means. According to aspects of the invention housing 32 contains a plurality of a plurality of photovoltaic (PV) devices 40, for example, devices adapted to receive solar energy and convert the solar energy to electrical energy, as known in the art. According to one aspect, the plurality of PV devices 40 are arranged or intermingled with reflective surfaces 42, specifically, surfaces adapted to reflect or concentrate sunlight on to PV devices 40. In one aspect of the invention, housing 32 may contain a solar energy concentrator and heat exchanger 44 comprising PV devices 40 and reflective surfaces 42. Accordingly, in one aspect, the front portion 34 of housing 32 may comprise a light-transmitting barrier 46, for example, a barrier translucent or transparent to solar radiation, whereby PV devices 40 and reflective surfaces 42 can be exposed to and capture solar radiation. Barrier 46 may be made from glass, for example, or a plastic. In one aspect, barrier 46 may be shaped to minimize wind load, for example, be curved to comply with a teardrop shape profile to minimize wind resistance.

The rear housing portion 36 of housing 32 of PV module 16 may include lower panel 61 having a plurality of light sources 50, for example, a plurality of LED lights. In one aspect, the plurality of light sources 50 may provide a wide angle of illumination to illuminate the vicinity of the tower or collector 10. As also shown in FIGS. 6 through 9, rear 36 of housing 32 may typically comprise a rear panel 48, for example, a transparent or translucent panel, adapted to allow passage of light from light sources 50. In one aspect, rear panel 48 may be shaped to minimize wind load, for example, be curved to comply with a tear-drop shape profile to minimize wind resistance.

As shown most clearly, in FIGS. 6, 7, and 9, in one aspect, the housing 32 may be streamlined or contoured, for example, streamlined to minimize drag due to any wind, as indicated by streamlines 51 in FIG. 9. It will be apparent to those of skill in the art that, since aspects of the invention may typically be elevated, tower assembly 10 and modules 16 may be exposed to wind loads. According to one aspect of the invention, tower assembly 10 is adapted to minimize or prevent wind loads on tower assembly 10, and thus minimize or prevent wind loading pole 12 and/or base 14. In one aspect, wind loads may be minimized by streamlining or contouring housing 32 of the modules 16. For example, as shown in FIGS. 6, 7, and 9, the from housing portion 34 and the rear housing portion panel 36 of housing 32 may be smoothly contoured to minimize wind drag or, as referred to in the art, to “ride the wind.” As shown in FIG. 9, in one aspect, housing 32 may be radiused R, for example, comprising one or more radiused surfaces. Though in one aspect, housing 32 may comprise single radiused sections 52 and 54, as shown in FIG. 9, in other aspects, housing 32 may comprise multiple radiused sections. For example, sections 52 and 54 may have radii of from about 6 inches to about 6 feet. However, it will be apparent to those of skill in the art that the radius of any section of housing 32 may be a function of the size of module 16, among other things. In one aspect, housing 32 may be symmetric about a centerline 53, though in other aspects, panel 32 may be eccentrically contoured.

In another aspect, the rear-housing portion 34 of housing 32 may be reflective, for example, providing a mirrored surface. When reflective, the rear housing portion 34 of housing 32 may further enhance the solar energy capturing capability of aspects of the invention by, for example, providing a reflective surface that directs sunlight to PV devices, for instances, upon PV devices mounted in adjacent modules 16. Housing 34 may be metallic, for example, made from aluminum, or non-metallic, for example, made from a plastic. The size of housing 32 of module 16 may vary broadly, depending upon the specific parameters of the installation. However, in one aspect, housing 32 of module 16 may have a length ranging from about 2 feet to about 20 feet, but typically has a length between about 3 feet and about 10 feet; a width ranging from about 1 foot to about 6 feet, but typically has a width between about 2 feet and about 4 feet; and a height or thickness ranging from about 6 inches to about 4 feet, but typically has a height or thickness between about 1 foot and about 3 feet.

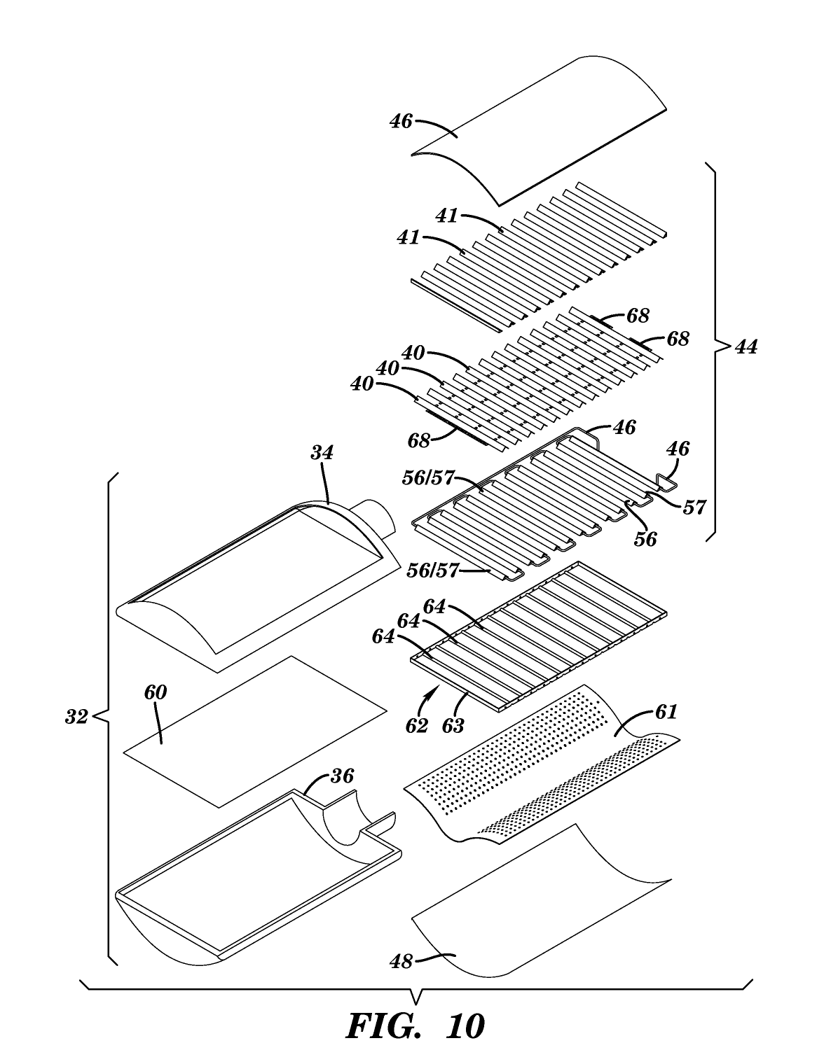

FIG. 10 is an exploded perspective view of the photovoltaic (PV) module 16 shown in FIGS. 6 through 9. As described above, PV module 16 includes a housing 32 having a front portion 34 and a rear portion 36, a front light-transferring barrier 46, a rear panel 61, and rear light-transferring barrier 48, and a solar concentrator and heat exchanger assembly 44. Among other things, assembly 44 includes PV devices 40 associated with appropriate electrical contacts or connections 68. As shown in FIG. 10, module 16 may also include an intermediate plate or panel 60 mounted within housing 32 adapted to support assembly 44 and module 16 may include a rack or tray 62 adapted to support assembly 44, for example, on plate or panel 60 in housing 32. Plate or panel 60 may be made of the same material of housing 32, for example, made of a metal or a plastic, and may be mounted in housing 32 by conventional means, for example, by brazing, by welding, or by mechanical fasteners. In one aspect, plate or panel 60 may be omitted.

As shown in FIG. 10, rack 62 may comprise a frame 63, for example, a rectangular frame, and a plurality of transverse bars 64. In one aspect, frame 64 and bars 64 are adapted to support solar concentrator and heat exchanger assembly 44. For example, in one aspect, transverse bars 64 may be positioned and sized to engage elongated cavities or recesses 45 in channels 41. For instance, in one aspect, transvers bars may be circular or semi-circular in shape and sized to engage elongated semi-circular cavities or recesses 45 in channels 41. Frame 63 and bars 64 may be metallic or plastic, and may be assembled by conventional means, for example, by brazing, by welding, or by mechanical fasteners.

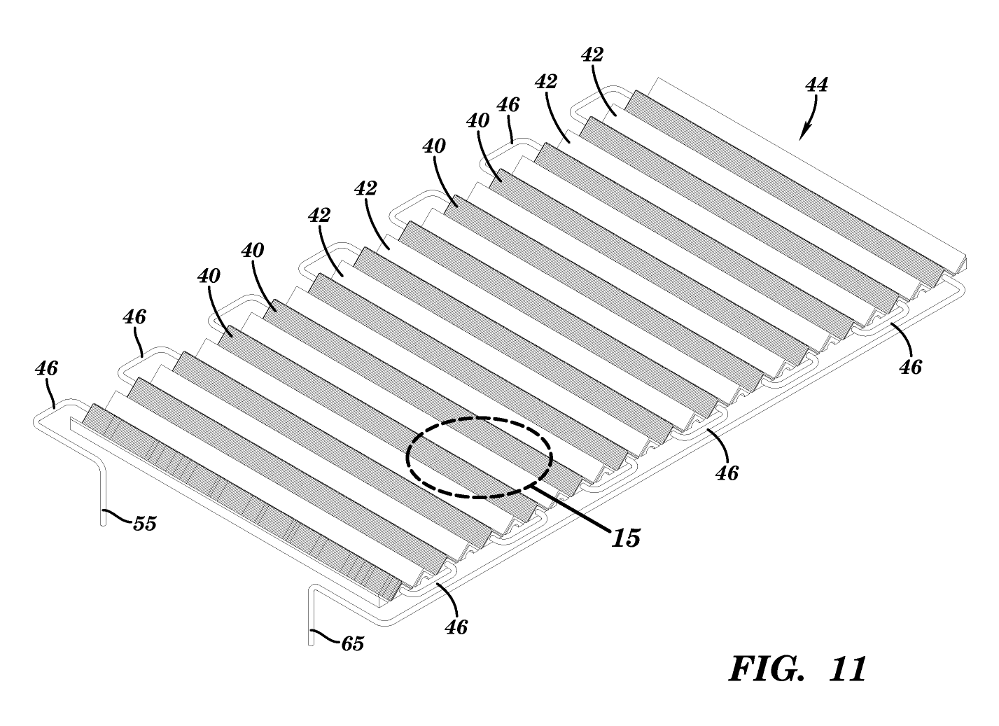

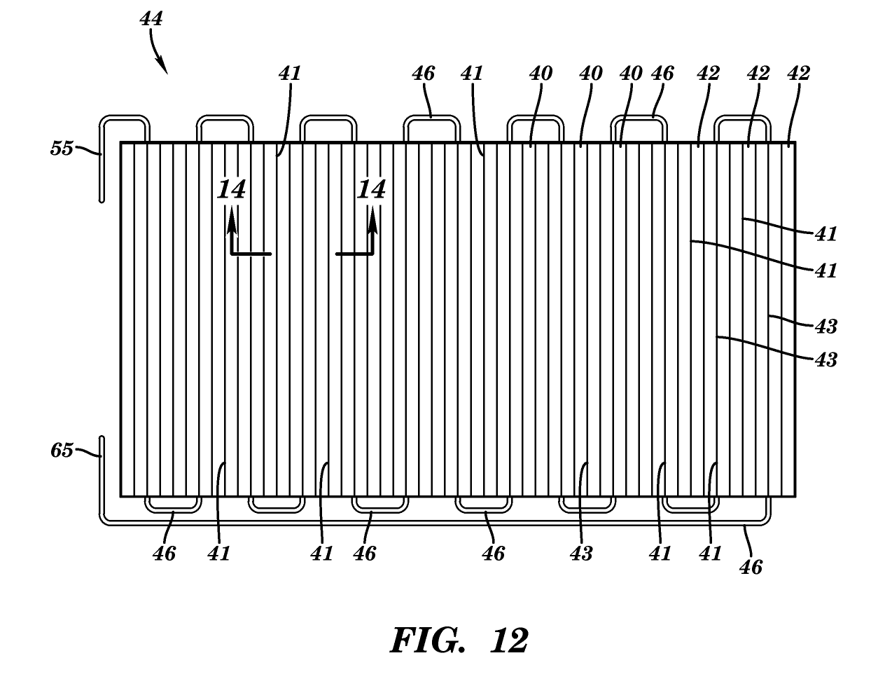

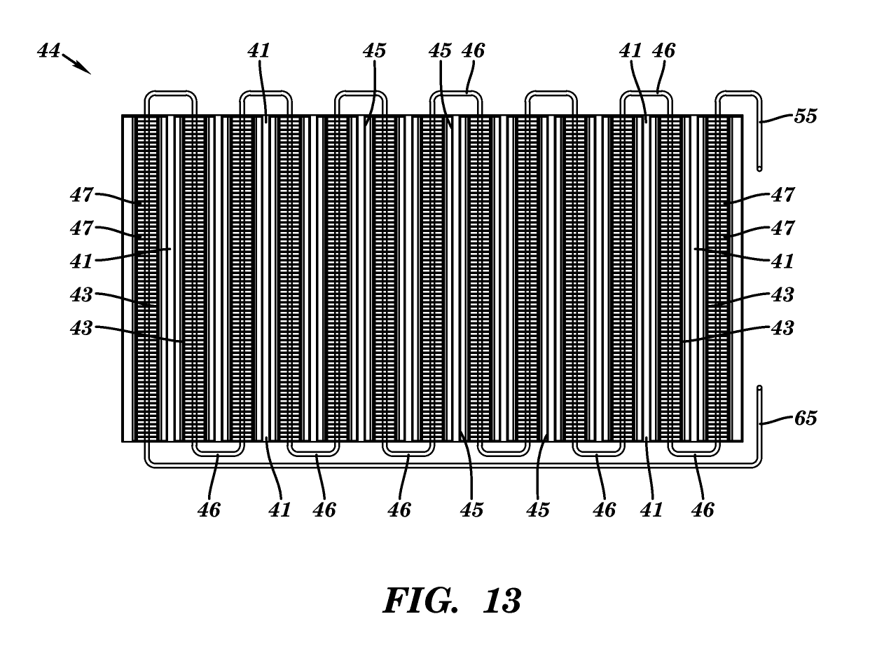

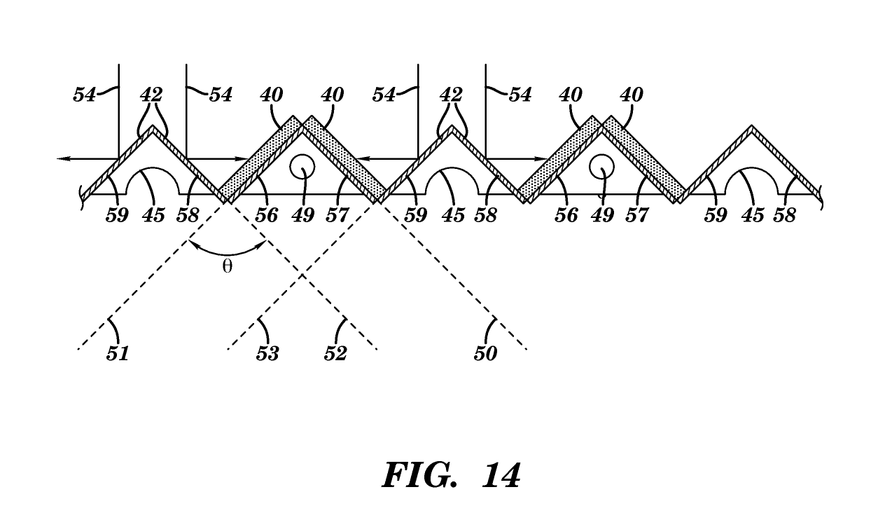

FIG. 11 is a perspective view of the solar concentrator and heat exchanger assembly 44 shown in FIG. 10. FIG. 12 is a front view of the solar concentrator and heat exchanger assembly 44 shown in FIG. 11 and FIG. 13 is a rear view of the solar concentrator and heat exchanger assembly 44 shown in FIG. 11. FIG. 14 is a cross sectional view of assembly 44 shown in FIG. 12 as viewed along section lines 14-14 shown in FIG. 12.

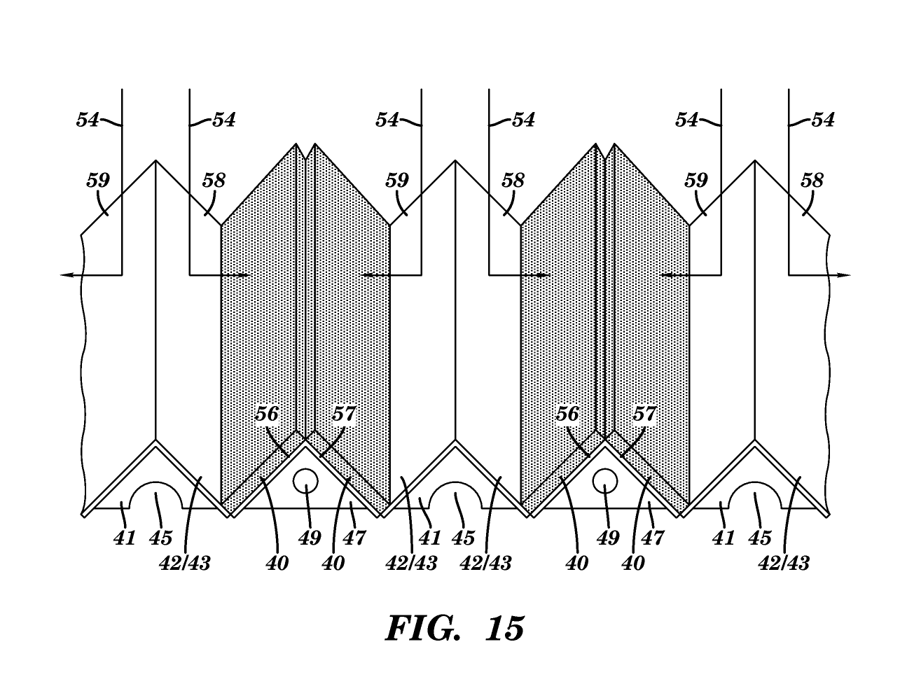

FIG. 15 is a detailed perspective view of the solar concentrator and heat exchanger assembly 44, partially in cross section, shown in FIG. 11 as identified by Detail 15 shown in FIG. 11.

As shown in FIGS. 10 through 13, solar concentrator and heat exchanger assembly 44 includes a plurality of PV devices 40 and a plurality of reflective surfaces 42 adapted to reflect or concentrate solar radiation upon PV devices 40. Though not shown, it is to be understood that PV devices 40, any PV devices disclosed herein, are electrically connected to electrical conductors, for example, wires or traces, to transfer the electrical energy generated by PV devices 40 to one or more electrical outputs, as is conventional.

As also shown in FIGS. 10 through 13, solar concentrator and heat exchanger assembly 44 is also adapted to transfer heat collected or generated by PV devices 40 and/or reflective surfaces 42 to a fluid, for example, a liquid or gas. For example, as shown in FIGS. 10 through 13, solar concentrator and heat exchanger assembly 44 includes a plurality of conduits 46 adapted to introduce a fluid, for example, a coolant, to assembly 44 at a first temperature and, after passing the fluid in heat exchange relationship with assembly 44, remove the fluid from assembly 44 at a second temperature, higher than the first temperature.

As shown in FIGS. 11, 12, and 13, in one aspect, the solar concentrator and heat exchanger assembly 44 may include a plurality of elongated members or channels 41 having reflective surfaces 42 and a plurality of elongated members or plates 43 where PV devices 40 are mounted to elongated plates 43, for example, mounted with ceramic paste. As shown most clearly in FIGS. 11 and 13, elongated channels 41 may comprise extruded channels, for example, triangular extruded channels. Though channels 41 may be solid, in the aspect shown, channels 41 may include cavities or recesses 45, for example, elongated cavities 45, to limit the weight of channels 41 and of assembly 44. As shown most clearly in the bottom view of FIG. 13, the plurality of conduits 46 may pass in heat exchange relationship with elongated plates 43, for example, to extract heat from PV devices 40 mounted on plates 43 and from the elongated plates 43. In one aspect, elongated plates 43 may comprise elongated channels, for example, solid channels or bars, or extruded elongated channels similar to channels 41. Conduits 46 may comprise one or more elongated through holes in each solid channel 43. However, as shown in FIG. 13, in this aspect, assembly 44 may include a plurality of plates or “fins” 47 mounted to elongated plates 43 and conduits 46 may pass through holes 49 in plates or fins 47 while being in thermal communication with plates 47. Plates or fins 47 may be shaped to adapt to the shape of elongated plates 43, for example, as shown in FIG. 11, plates or fins 47 may be triangular in shape to conform to the underside of triangular elongated plates 43. Soldering or welding may mount plates or fins 47 to plates 43 by conventional means, for example. Soldering, welding, or mechanical fasteners may also attach elongated plates 43 to elongated channels 41 by conventional means, for example. In addition, soldering, welding, or mechanical fasteners may mount assembly 44 in housing 32 of module 16 by conventional means, for example.

Elongated plates 43 and elongated channels 41 may have lengths ranging from about 1 foot to about 12 feet, but are typically have lengths ranging from about 2 feet to about 6 feet, for example, between about 3 feet to about 4 feet. Elongated plates 43 may have a plate thickness ranging from about 0.0625 inches to about 2 inches, but are typically have plate thicknesses ranging from about ⅛ inch to about 1 inch, for example, between about ¼ inch an about ½ inch. Plates or fins 47 may have a plate thickness ranging from about 0.03125 inches to about 1 inch, but typically have plate thicknesses ranging from about 0.0625 inches to about ¼ inch, for example, between about ⅛ inch and about ¼ inch.

As shown in FIGS. 11, 12, and 13, conduit 46 may comprise one or more conduits or one or more conduit circuits having one or more fluid inlets 55 and one or more fluid outlets 65. The cooling fluid or coolant passed through the one or more conduits 46 may be a gas, for example, nitrogen, or a liquid, for example, water or an alcohol, or a combination thereof. Though in one aspect, the fluid may be pressurized, for example, by means of a compressor or pump, in another aspect, the motive force for the fluid may be convention, for example, due to the heating in assembly 44 at different elevations of tower 10.

As shown in FIGS. 11 and 12, PV devices 40 and reflective surfaces 42 are arranged whereby the reflective surfaces 42 reflect solar radiation upon PV devices 40. According to one aspect of the invention, any arrangement of PV devices 40 and reflective surfaces 42 adapted to direct sunlight onto the PV devices 40 may be provided. In the aspect of the invention shown in FIGS. 11 and 12, which is most clearly illustrated in FIGS. 14 and 15, the PV devices 40 (not shown to scale to facilitate illustration) are positioned on a plurality of first inclined planes 50 and 51 and the reflective surfaces 42 are positioned on a plurality of second opposing inclined planes 52 and 53 whereby the solar radiation received by the reflective surfaces 42 on the plurality of second inclined planes 52 and 53 (as indicated by arrows 54) is reflected upon the plurality of PV devices 40 positioned on the first inclined planes 50 and 51 (as indicated by arrows 54). In the aspect shown in FIGS. 11 through 15, the location of the PV devices 40 and the reflective surfaces 42 are optimized to enhance the capture of solar radiation. Specifically, as shown in FIGS. 11 through 15, a plurality of inclined planes 50 and 51 bearing PV devices 40 are arranged opposite a plurality of inclined planes 52 and 53. As shown in FIG. 11, this arrangement of inclined planes is then repeated to span at least a portion of the front portion 34 of module 16, for instance, substantially the entire front portion 34 of housing 32 of module 16, for example, the entire length and width of module 16.

As shown most clearly in FIGS. 14 and 15, in one aspect, PV devices 40 (shown as shaded surfaces in FIG. 15) may be positioned on a first panel, plate, or substrate 56 defining a first plane 51 and reflective surfaces 42 (shown as unshaded surfaces in FIG. 15) may be positioned on a second panel or plate 58 defining a second plane 52 whereby the first plane 51 of the first panel 56 forms an angle, θ, with the second plane 52 of the second panel 58. In one aspect, the first panel or plate 56 and the second panel or plate 58 may be formed from the same panel or plate, for example, a panel or plate bent at an angle θ. As shown in FIGS. 14 and 15, plates 56 having PV devices 40 and plates 58 having reflective surfaces 42 may be repeated as needed, for example, to span at least a portion of the surface of assembly 44 of module 16. For example, plates 56 having PV devices 40 may be paired with a complementary panels, plates, or substrates 57 having PV device 40 and plates 58 having reflective surfaces 42 may be paired with complementary plates 59 having reflective surfaces 42, for instance, to provide the repeating pattern of PV devices 40 and reflective surfaces 42 shown in FIGS. 11, 12, and 15. In one aspect, the plates 56 and 57 having PV devices 40 may be formed from the same panel or plate, for example, a panel or plate bent at an angle θ. In another aspect, plates 58 and 59 having reflective surfaces 42 may be formed from the same panel or plate, for example, a panel or plate bent at an angle θ. In a further aspect, plates 56 and 57 having PV devices 40 and plates 58 and 59 having reflective surfaces 42 may all be formed from the same panel or plate, for example, a panel or plate having a plurality of bends at an angle θ, for instance, that can be formed into a desired shape by pressing.

According to aspects of the invention, the angle θ may vary from 30 degrees to about 150 degrees, but is typically between about 75 degrees and about 105 degrees, and is preferably between about 85 degrees and 95 degrees, for example, angle θ may about 90 degrees.

As shown in FIG. 14, according to one aspect, the plane 50 of panel 57 having PV devices 40 may make an angle δ with the plane 51 of panel 56 having PV devices 40. In like manner, the plane 52 of panel 58 having reflective surfaces 42 may make an angle δ with the plane of panel 59 having reflective surfaces 42. According to aspects of the invention, the angle δ may vary from 30 degrees to about 150 degrees, but is typically between about 75 degrees and about 105 degrees, and is preferably between about 85 degrees and 95 degrees, for example, angle δ may about 90 degrees

Typically, the panels or plates 56 and 58 may be thermally conductive, for example, whereby any thermal energy received or absorbed by the PV devices 40, reflective surfaces 42, and panels or plates 56, 57, 58, and 59 may be conducted away to a heat sink, for example, a cooling fluid, as discussed above with respect to FIGS. 11 through 13. For example, in one aspect, plates 56, 57, 58, and 59 may be metallic, for instance, containing at least some aluminum or copper. In one aspect, plates 56, 57, 58, and 59 may be made from copper.

The PV devices 40 may be any conventional PV devices adapted to convert solar energy to electrical energy, for example, conventional solar cells, and the like.

The reflective surfaces 42 may comprise any surface adapted to reflect at least some solar radiation, for example, visible light. The reflective surfaces 42 may comprise metallic surfaces, for example, surfaces of the metallic plates 58 and 59, for instance, polished metal surfaces. The reflective surfaces 42 may comprise mirrored surfaces, for example, a material having a reflective coating, for example, a metallic coating or a ceramic coating, providing at least some reflection. In one aspect, the reflective surfaces 42 may have a reflectivity of at least 0.50, typically, a reflectivity of at least 0.75, preferably, a reflectively of at least 0.90.

In one aspect, the invention may exhibit substantially a single reflection of solar radiation from, for example, reflective surfaces 42 to PV devices 40, for example, as illustrated in FIGS. 14 and 15. However, according to another aspect of the invention, multiple reflections of solar radiation may be practiced to direct or concentrate solar radiation on PV devices, for example, PV devices 40. In one aspect of the invention, 2 or more reflections may be practiced or 3 or more, 4 or more, 5 or more, and even 10 or more reflections may be practiced. It is envisioned that, according to some aspects of the invention, the number of reflections of solar radiation that can be practiced may only be limited by the capability of existing manufacturing processes, for example, as will soon be apparent to those of skill in the art, limited to the capabilities of available micro- or nano-photolithographic processes.

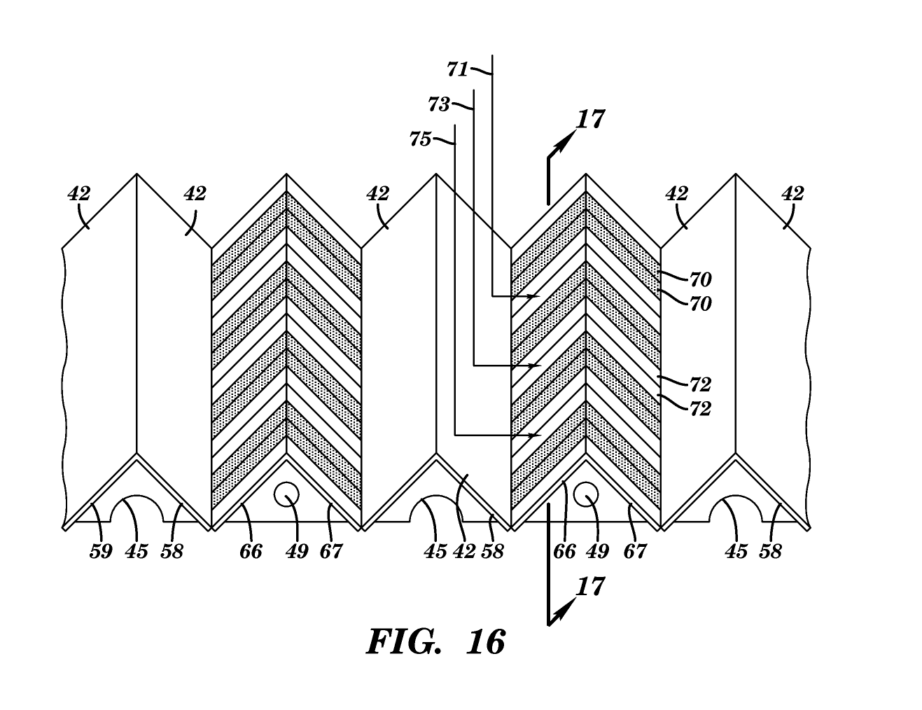

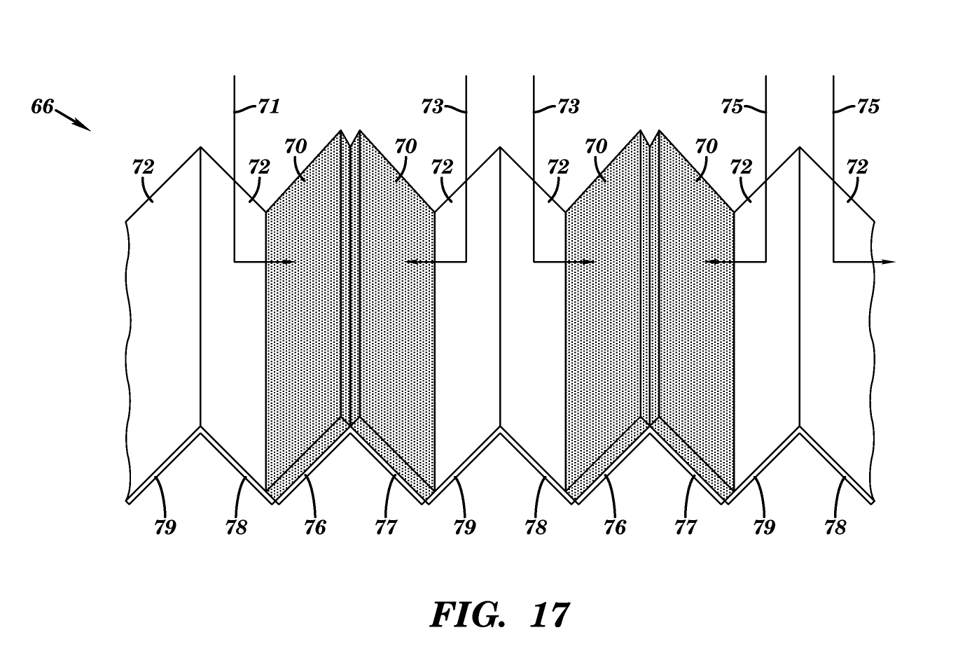

FIGS. 16 and 17 illustrate another aspect of the invention practicing multiple reflections. As will become apparent, though FIGS. 16 and 17 illustrate an aspect where only two reflections are practiced, it will be apparent to those of skill in the art that the aspect of the invention shown in FIGS. 16 and 17 may be repeated at least once, but may also be repeated multiple times to concentrate solar radiation upon PV devices.

FIG. 16 is a detailed perspective view of a portion of FIG. 11, similar to FIG. 15; however, in this aspect, instead of panels 56 and 57 having only PV devices 40 as indicated in FIG. 15, panels 66 and 67 in FIG. 16 have both PV devices 70 and reflective surfaces 72. In other words, in the aspect of the invention shown in FIG. 16, the alternating pattern of PV devices 40 and reflective surfaces 42 shown in FIG. 15 is mimicked with a decreased dimension as alternating PV devices 70 and reflective surfaces 72 on panels 66 and 67 in FIG. 16.

This disclosure of the aspect of the invention shown in FIGS. 16 and 17 is facilitated with the depiction of the envisioned typical impact of solar radiation upon the PV devices 70 and reflective surfaces 72 on panel or plate 66 illustrated by arrow 71, 73, and 75 in FIGS. 16 and 17. As shown in FIG. 16, solar radiation 71, 72, and 73 impact and respectfully reflect from reflective surface 42 on panel or plate 58 onto plate 66 having PV devices 70 (shown as shaded surfaces in FIGS. 16 and 17) and reflective surfaces 72 (shown as unshaded in FIGS. 16 and 17). As shown in FIG. 17, solar radiation 71, 73, and 75 which was reflected from reflective surface 42 is directed to PV devices 70 and reflective surfaces 72 which, as shown in FIG. 1, further reflect the solar radiation 71, 73, and 75 upon PV devices 70. Accordingly, according to the aspect of the invention shown in FIGS. 16 and 17, incoming solar radiation is reflected twice: once from reflective surfaces 42 on panels 58 and 59 shown in FIG. 16, and then from reflective surfaces 72 on panels 78 and 79 shown in FIG. 17.

Moreover, it will be apparent to those of skill in the art, that the aspect of the invention disclosed in FIGS. 16 and 17 may be further extended to panels 76 and 77 in FIG. 17 by replacing PV devices 70 on panels 76 and 77 with further reflective surfaces and PV devices (which are not shown for the sake of brevity). For example, this aspect of the invention may provide for the practice of three or more reflections. However, the further reflective surfaces and PV devices that may be provided on panels 76 and 77 may have substantially the same characteristics, orientation, and/or relationships to each other, for example, the same angle θ discussed previously, or the same reflective surface, or the same plate material. In addition, according to aspects of the invention, further repetition of the arrangement shown in FIGS. 16 and 17 to further surfaces and subsurface can be used to provide further reflection and concentration of solar energy.

The aspects of the invention shown in FIGS. 13 through 17 illustrate features of the invention whereby solar radiation may be reflected, for example, multiple times, to, for example, concentrate the flux of solar radiation upon PV devices and enhance the capture of solar energy. According to one aspect, this concentration of solar energy is characterized by a one-directional or planar concentration of solar energy, that is, the reflection of solar energy upon PV devices may be considered reflected in multiple times within one plane, for example, as exemplified by the refection of solar radiation 54 in FIG. 15. However, as disclosed below, aspects of the invention may include the reflection and/or concentration of solar energy in multiple planes, that is, in multiple directions.

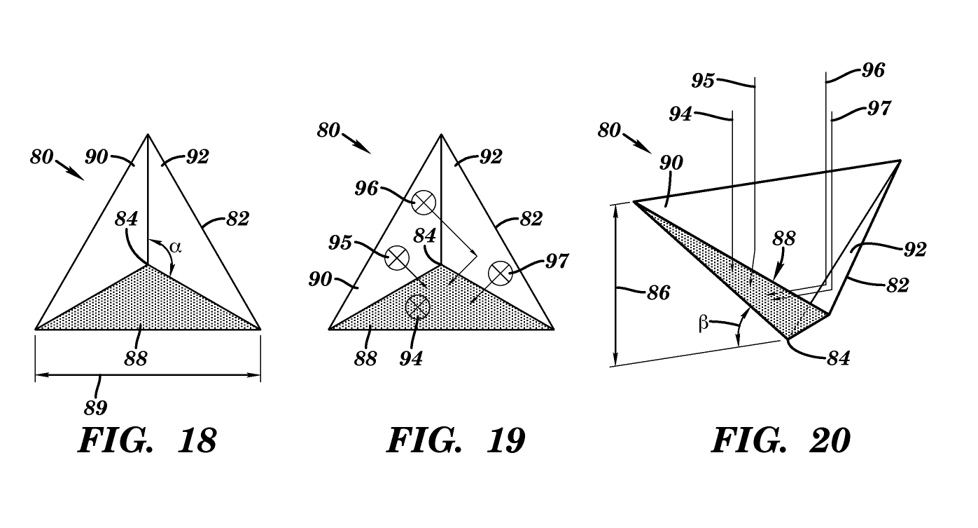

FIG. 18 is a plan view of solar energy concentrating “cell” 80 according to another aspect of the invention. Typically, a plurality of cells 80 may be positioned in a solar concentrator and heat exchanger 44 in a module 16, see FIGS. 5 through 10. However, in one aspect, an arrangement of a plurality of cells 80 may be used in any application where solar energy is captured and/or concentrated, for example, on a PV panel. FIG. 19 is a plan view a cell 80, similar to FIG. 18, and illustrates typical pathways of solar radiation that may be captured with a cell 80. FIG. 20 is a perspective view of cell 80 providing a perspective view of the solar radiation pathways shown in FIG. 19.

As shown in FIG. 18, cell 80 comprises a three dimensional triangular structure, or an inverted pyramidal structure, having a base 82, an apex 84 positioned at a depth 86 from the base 82, and three planar surfaces or sides, 88, 90, and 92. Planar surfaces 88, 90, and 92 may typically be triangular in shape and define an apex angle α. Apex angle α may be approximately the same for each surface 88, 90, and 92, for example, about 120 degrees, but in some aspects, apex angle αmay vary among surfaces 88, 90, and 93. The length 89 of the sides of base 82 may also be about the same for each surface 88, 90, and 92, but in some aspects the length 89 of the sides of base 92 may vary. Also, as shown in FIG. 20, the edges of the surfaces 88, 90, 92 may make an angle β with the plane of base 92, for example, the angle β may range from about 5 degrees to about 85 degrees, but is typically, between about 30 degrees and about 60 degrees, for example, and angle β may be about 45 degrees.

According to one aspect of the invention, at least one of surfaces 88, 90, and 92 comprises a plurality of PV devices, and at least one of the surfaces 88, 90, and 92 comprises a reflective surface. For example, at least one of the surfaces 88, 89, and 92 may include a plurality of PV devices 40, as described above, and at least one of the surfaces 88, 90, and 92 may include a reflective medium similar to reflective surfaces 42, as described above. Also, surfaces 88, 90, and 92 may be surfaces supported on plates or panels, for example, metallic plates or panels, for instance, surfaces 88, 90, and 92 may comprise surfaces fabricated from one or more plates or panels, for example, by molding or pressing, among other fabrication methods.

As shown in FIGS. 18 through 20, cell 18 may typically comprise one surface 88 having a plurality of PV devices 94 (shown shaded in FIGS. 18 through 22) and two surfaces, 90 and 92, comprising reflective surfaces (shown unshaded in FIGS. 18 through 22). FIGS. 19 and 20 illustrate the paths of a few typical solar radiation beams, represented by arrow tails 94, 95, 96, and 97 in FIG. 19, and arrows 94, 95, 96, and 97 in FIG. 20. For example, solar radiation beam 94 may directly illuminate PV devices on surface 88; solar radiation beam 95 may reflect from surface 90 and then illuminate PV devices on surface 88; solar radiation beam 96 may first reflect from surface 90, then reflect from surface 92, and then illuminate PV devices on surface 88; and solar radiation beam 97 may reflect form surface 92 and then illuminate PV devices on surface 88. The arrows and arrow tails 94, 95, 96, and 97 are representative of just of few paths of solar radiation beams; as will be known in the art, solar radiation will effectively continuously illuminate surfaces 88, 90, and 92 to capture and concentrate solar energy on the PV devices positioned on surface 88.

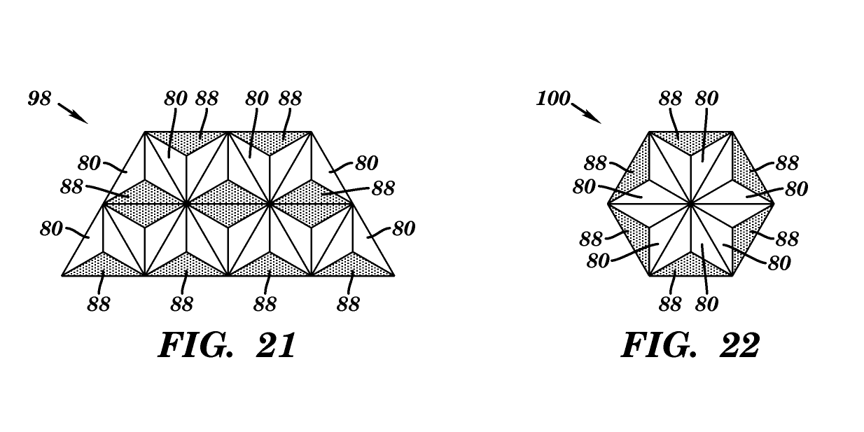

Cell 80 shown in FIGS. 18, 19, and 20 represents one cell 80 of a plurality of cells that may be used. For example, FIGS. 21 and 22 illustrate two typical arrangements 98 and 100 of pluralities cells 80 that may be used according to aspects of the invention, for example, span at least a portion of the surface of assembly 44 of module 16. The arrangements 98 and 100 may be repeated as necessary to cover the desired surface being illuminated by solar radiation. It will be apparent to those of skill in the art that a myriad of possible arrangements may be envisioned for arranging a plurality of individual cells 80. For the sake of brevity, only a few arrangements 98 and 100 are presented, but others are within the scope of the present invention.

FIGS. 18 through 22 illustrate aspects of the invention in which the reflective or PV surfaces are positioned in “depressions,” for example, from a surface. That is, one aspect of the invention is characterized by numerous pyramidal “holes” in a surface or plane. According to another aspect of the invention, cells 80 may comprise “projections,” for example, from a surface a plane. That is, cells 80 may comprise pyramidal “bumps” or “mounds” positioned above a surface or plane. For instance, though FIG. 18 was descried herein with regard to the “depression” or “hole” aspect of the invention, FIG. 18 may also represent the aspect of the invention where cell 80 represents a projection. In this aspect, instead of solar radiation being directed upon PV devices positioned upon an internal surface of a pyramidal structure, in the projection aspect, solar radiation may be reflected from the surface of one projection 80 upon an external surface of another adjacent projection 80 having PV devices. In addition, this aspect of the invention where the cells 80 comprises projections is also applicable to the arrangements 98 and 100 shown in FIGS. 21 and 22, where cells 80 would be projections instead of depressions.

In addition, though cells 80 were described herein as pyramidal structures having three (3) faces and a base, it will be apparent to those of skill in the art that aspects of the invention are also applicable to pyramidal structures having more than three faces and a base. In one aspect, cell 80 may have 4 or more internal or external faces, 88, 90, and 92 and a base 82; or 5 or more internal or external faces 88, 90, and 92 and a base 82. It is envisioned that the number of internal and external faces that may be provided for cell 80 may only be limited by the capabilities of the available manufacturing processes.

It will also be apparent to those of skill in the art that the pyramidal structure of cell 80 may not include a pointed apex 84, for example, apex 84 may be a surface, for example, flat, rounded, or curved surface. In one aspect, the shape of apex 84 may be a flat surface, for example, flat base of a depression or a table-like structure of a projection. It will be understood that the shape of apex 84 may also be a function of the capabilities of the available manufacturing processes.

According to one aspect of the invention, the plurality of cells 80 may be positioned to be used wherever PV devices are used, for example, in any PV device application. However, in one aspect, the plurality of cells 80 may be positioned in module 16, for example, in assembly 44, to capture or concentrate solar radiation. For example, a plurality of cells 80 may be used to replace the alternating rows of PV devices 40 and reflective surfaces 42 shown in FIGS. 11 through 15. In another aspect, a plurality of cells 80 may also be used to replace the alternating rows of PV devices 70 and reflective surfaces 72 shown in FIGS. 16 and 17. It is also envisioned that, according to a further aspect of the invention, a plurality of cells 80 may be located on surfaces 88 in FIGS. 18 through 22 where cells 80 provide means for practicing multiple reflection of solar radiation, for example, in a fashion similar to the multiple reflections disclosed with respect to FIGS. 17 and 18. As in the earlier embodiment, it is envisioned that, according to some aspects of the invention, the number of sub-regions or surfaces of PV devices and the number of reflections of solar radiation that can be practiced by using cells 80 may only be limited by the capability of available manufacturing processes, for example, upon the limits of the capabilities of micro- or nano-photolithographic processes.

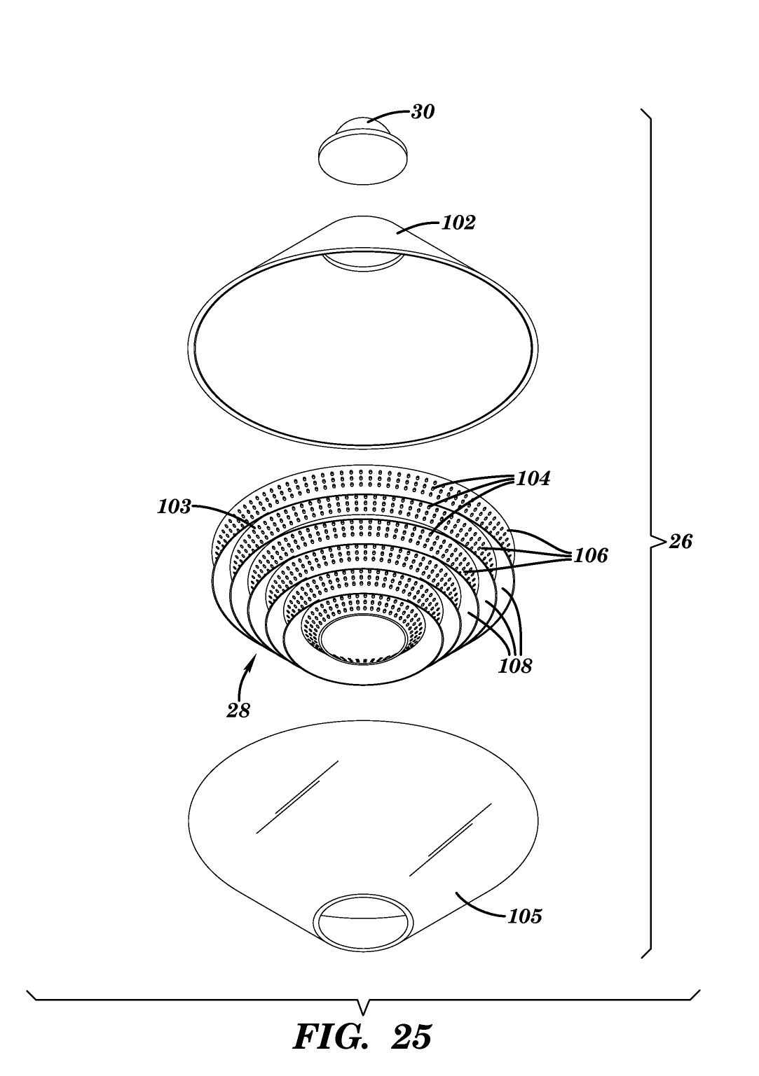

FIG. 23 is a top perspective view of the light assembly 26 of the photovoltaic tower 10 shown in FIG. 1 according to one aspect of the invention. FIG. 24 is a bottom perspective view of light assembly 26 of photovoltaic tower 10 shown in FIG. 1 and FIG. 25 is an exploded top perspective view of light assembly shown 26 in FIGS. 23 and 24. As shown, light assembly 26 is mounted to pole or shaft 12, for example, to the top of pole 12 by conventional mounting means, such as, mechanical fasteners, and includes a top cover or shroud 102 adapted to protect the light sources underneath and to deflect precipitation. For example, as shown, in one aspect, cover 102 may be conical in shape and comprise a sheet of metallic or non-metallic material, for example, aluminum or a plastic. A plurality of light sources 28 may be positioned beneath cover 102, for example, positioned in a bottom cover 103 mounted beneath top cover 102. Light sources 28, for example, a plurality of individual light sources 104, for instance, LED light sources (though in aspects of the invention any light sources may be used), may be powered by the solar energy captured by one or more of the PV modules 16 disclosed herein. In one aspect, light sources 104 are positioned in a plurality of concentric circles 106. For example, the plurality of light sources 104 may be positioned in six (6) sets of rows of concentric circles 106, though the number of rows of concentric circles 106 may vary. According to one aspect of the invention, the illumination of rows of concentric circles 106 of individual light sources 104 may vary to vary the amount of illumination provided to the vicinity of collector 10.

As also shown in FIGS. 23 through 25, light assembly 26 may also include a plurality of baffles or “fins” 108 mounted between rows of concentric circles 106 of individual lights 104, for example, mounted to bottom cover 103 by conventional means. As shown, baffles or fins 108 may be conical in shape or may be right circular cylindrical in shape, and may be evenly radially spaced about light assembly 26. Light assembly 26 may include a transparent or translucent bottom cover 105, for example, a conical cover, adapted to protect individual lights 104 and baffles 108.

In one aspect, light assembly 26 may also include one or more sensors, detectors, or cameras 30, for example, a detector adapted to detect the amount of sunlight available, or a security camera adapted to detect images of the area about the collector 10, for example, in an adjacent parking lot or parking garage.

FIG. 26 is a perspective view of a photovoltaic module 16 mounting and drive assembly 110 for the tower shaft 12 shown in FIG. 1. Mounting and drive assembly no is adapted to mount one or more modules 16 onto shaft 12 while providing means for rotating modules 16, for example, to orient modules 16 to optimize the exposure of the PV devices in modules 16 to sunlight. As shown in FIG. 26, mounting and drive assembly 110 comprises a hub 112 mounted to shaft 12 and at least one, but typically two, module drive shafts 114. Drive shafts 114 engage a drive mechanism (not shown) in hub 112 and engage modules 16, for example, engage the housings 32 of modules 16, for example, by means of mechanical fasteners (not shown).

FIG. 27 is an exploded perspective view of a photovoltaic module mounting and drive assembly 110 shown in FIG. 26. In one aspect, mounting and drive assembly no may include a source of motive force, such as, an electric or hydraulic motor with an appropriate gearbox or transmission. As shown in FIG. 27, in one aspect, mounting and drive assembly no may include one or more pulleys, sheaves, or sprockets 116 mounted for rotation within a housing 118 of hub 112, for example, on a shaft 119. Shaft 119 may typically be operationally connected to drive shafts 114 of modules 16 (shown in phantom) to rotate modules 16 as desired. Drive assembly no may include one or more appropriate friction-reducing bearings 117, such as, roller bearings, and fluid seals (not shown) adapted to rotatably mount pulleys or sprockets 116 in housing 118. Pulleys or sprockets 116 may engage one or more chains or belts 120 driven remotely, for example, driven by a motor-driven sprocket or pulley mounted in base 14 (not shown) and accessing pulley or sprocket 116 via the hollow interior of shaft 12, among other paths. Assembly 110 may also include means for transmitting power/rotation to other mounting and drive assemblies no mounted on shaft 12, for example, one or more pulleys, sheaves, or sprockets 116 mounted on shaft 119 and adapted to drive a chain or belt 120 operatively connected to another assembly no, for example, to a pulley, sheave, or sprocket of a similar assembly 10 associated with one or more modules 16 located at an upper and/or lower elevation on shaft 12.

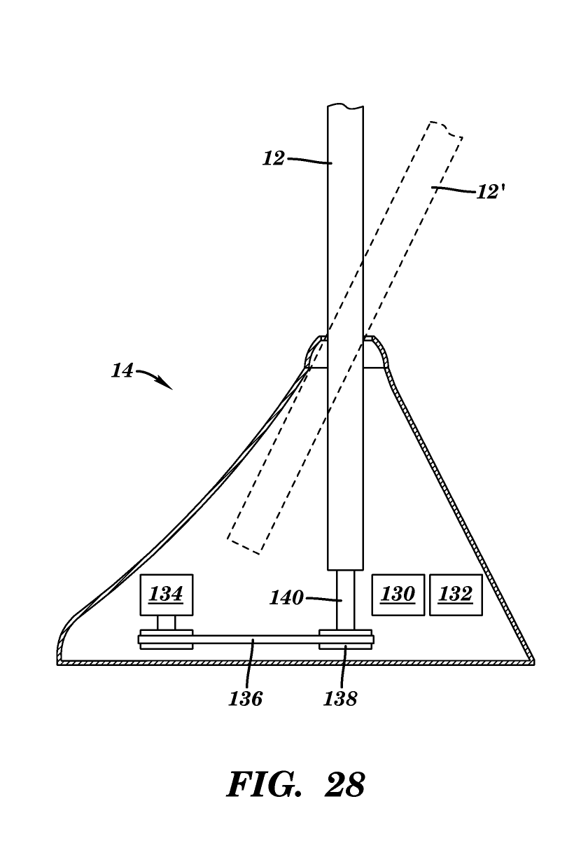

FIG. 28 is an elevation view of the base assembly 14 of the tower assembly 10 shown in FIG. 1 with its cover partially removed to reveal some of the inner components in the base assembly 14. According aspects of the invention, base assembly 14 may include one or more storage batteries 130 operatively connected to the PV devices in modules 16, may include one or more pumps 132 operatively connected to the coolant circulated through modules 16 (for example, via conduits directed to modules 16, for instance, within pole 12), and may include one or more drive motors 134 adapted to rotate pole 12. For example, as shown in FIG. 28, drive motor 134 may drive a belt 136 that engages a pulley 138 operatively connected to pole 12 by shaft 140. In one aspect, base assembly 14 may also include means for varying the orientation or “tilt” of pole 12, for example, one or more stepper motors (not shown) (for example, three motors) adapted engage and tilt shaft 12, for example, as shown in phantom as tilted shaft 12′ in FIG. 28 and also in FIG. 29. In one aspect, the tilting of pole 12 may be effected by the use of concentric rings adapted to support pole 12, for example, by means of a plurality of elastic members, such as, springs, pulleys, and/or tension members. In addition, base 12 may include one or more controllers and/or logic boards, for example, to control the operation of tower 10, to monitor or regulate the electric energy captured and, for example, stored in the batteries 130. Base assembly 14 may also include a user interface and/or a maintenance or control interface, for example, for use by technicians to operate, adjust, service, and/or monitor the operation of tower 10.

FIG. 29 is an elevation view the tower assembly 10 shown in FIG. 1 as tilted to enhance solar energy capture according to one aspect of the invention. As shown in FIG. 29, in one aspect, base 14 is adapted to allow shaft 12 to vary its vertical orientation, that is, for example, to “tilt” to enhance the exposure of the PV devices 40 in PV modules 16 to solar radiation. In the aspect shown in FIG. 29, for example, solar radiation from the sun 150 at an angle above the horizon, σ, is depicted by parallel arrows 152. In addition, as described above with respect to FIGS. 27 and 28, in one aspect, the orientation of one or more PV modules 16 may be varied, for example, via mounting and drive assemblies 110 (shown in phantom in FIG. 29).

In one aspect, the relative location of modules 16 along shaft 12 may be optimized to maximize exposure to solar radiation 152 while minimizing or preventing the obstruction of the paths of solar radiation 152 upon other PV modules 16. For example, as shown in FIG. 29, the separation 154 between PV modules 16 along shaft 12 may be predetermined as a function of, among other things, the latitude of the location of tower assembly 10; the longitude of the location of tower assembly 10; the elevation of the sun 150, σ; and the size, for example, the length and the width, of module 16. According to one aspect of the invention, the separation 154 between modules 16 may be provided whereby when the orientation of shaft 12 is varied, for example, as indicated by angle γ, the obstruction of the PV devices in modules 16 is minimized or prevented. For example, as shown schematically in FIG. 29, in one aspect, the separation 154, among other things, can be controlled whereby the shadows 160 thrown by PV modules 16 due to solar radiation 152 do not fall on any PV devices in PV modules 16. This is shown schematically in FIG. 29 by the edges of shadows 160 failing to fall on PV modules 16 and accordingly not obstructing any PV devices in PV modules 16.

The inventor submits that from the above description it is clear that aspects of the present invention provide solar energy collectors, systems, devices, and methods for capturing solar that are no only effective and versatile, but also provide a aesthetically attractive design. By raising and positioning PV devices in a tower or tree-like structures, aspects of the present invention also provide a PV installation that is more conducive to areas lacking the space typically required by conventional PV systems. In addition, due to the multiple reflections of solar radiation that can be provided by aspects of the invention, the solar energy flux that can be directed upon PV devices, that is, upon any type of PV devices, is enhanced compared to conventional PV or CPV systems and methods. As will be appreciated by those skilled in the art, features, characteristics, and/or advantages of the various aspects described herein, may be applied and/or extended to any embodiment (for example, applied and/or extended to any portion thereof).

Although numerous aspects of the present invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

1. A solar energy collector comprising:
an elongated pole;
a plurality of photovoltaic modules pivotally mounted to the pole at a plurality of elevations, wherein each of the plurality of modules comprises:
a housing; and
a plurality of photovoltaic devices mounted in the housing;
a drive mechanism adapted to rotate each of the pivotally mounted photovoltaic modules; and
a base assembly adapted to support the pole.

2. The solar energy collector as recited in claim 1, wherein each of the plurality of photovoltaic modules further comprise:
a photovoltaic energy heat exchanger mounted in the housing comprising:
a plurality of elongated, thermally conductive panels, wherein the plurality of photovoltaic devices mounted in the housing comprise a plurality of photovoltaic devices mounted to and in thermal communication with at least some of the plurality of thermally conductive panels;
a plurality of reflective surfaces positioned to reflect sunlight on the plurality of photovoltaic devices; and
a cooling fluid conduit in thermal communication with at least some of the plurality elongated, thermally conductive panels.

3. The solar energy collector as recited in claim 2, wherein the plurality of elongated, thermally conductive panels comprises a plurality of first elongated, thermally conductive panels, wherein the photovoltaic energy heat exchanger further comprises a plurality of second elongated, thermally conductive panels, wherein a plane of each of the plurality of second panels forms an angle with the plane of one of the plurality of first panels, and wherein the plurality of photovoltaic devices mounted in the housing further comprises a plurality of photovoltaic devices mounted to and in thermal communication with the plurality of second elongated, thermally conductive panels.

4. The solar energy collector as recited in claim 3, wherein the plurality of reflective surfaces comprises a plurality of first reflective surfaces positioned to reflect sunlight on the plurality of photovoltaic devices mounted on the plurality of first elongated panels, and a plurality of second reflective surfaces positioned to reflect sunlight on the plurality of photovoltaic devices mounted on the plurality of second elongated panels.

5. The solar energy collector as recited in claim 1, wherein the base is adapted to pivotally support and rotatably support the pole.

6. The solar energy collector as recited in claim 1, wherein the solar energy collector further comprises a light assembly mounted to the pole.

7. The solar energy collector as recited in claim 3, wherein the plurality of photovoltaic modules comprises at least two pairs of modules, each of the at least two pairs of modules pivotally mounted at at least two elevations to the pole.

8. The solar energy collector as recited in claim 1, wherein each of the plurality of photovoltaic modules further comprise:
a photovoltaic energy heat exchanger mounted in the housing comprising:
a plurality of pyramidal structures, wherein the plurality of photovoltaic devices mounted in the housing comprise a plurality of photovoltaic devices mounted to and in thermal communication with at least one face of each of the plurality of the pyramidal structures;
a plurality of reflective surfaces, each of the plurality of reflective surfaces positioned on at least one face of each of the plurality of the pyramidal structures, the plurality of reflective surfaces positioned to reflect sunlight on the plurality of photovoltaic devices; and
a cooling fluid conduit in thermal communication with at least some of the plurality of pyramidal structures.

9. The solar energy collector as recited in claim 9, wherein the plurality of pyramidal structures comprises at least one of a plurality of pyramidal recesses and a plurality of pyramidal projections.

10. The solar energy collector as recited in claim 1, wherein the plurality of photovoltaic modules comprise aerodynamic housings that minimize wind load on the collector.

11. A method for collecting solar energy comprising:
pivotally mounting a plurality of photovoltaic modules to a pole at a plurality of elevations, wherein each of the plurality of modules comprises:
a housing; and
a plurality of photovoltaic devices mounted in the housing and adapted to receive solar energy and convert the solar energy to electrical energy;
pivoting each of the plurality of photovoltaic modules about an axis to vary the amount of solar energy received by the plurality of photovoltaic devices; and
supporting the pole in a base assembly.

12. The method recited in claim 11, wherein the method further comprises rotating the pole about the base to further vary the amount of solar energy received by the photovoltaic devices.

13. The method recited in claim 11, wherein the method further comprises pivoting the pole about the base to further vary the amount of solar energy received by the photovoltaic devices.

14. The method recited in claim 11, wherein the plurality of photovoltaic devices generate thermal energy, and wherein the method further comprises conducting the thermal energy away from the plurality of photovoltaic devices by passing a cooling fluid in thermal communication with the plurality of photovoltaic devices.

15. The method recited in claim 14, wherein the cooling fluid comprises at least one of a liquid and a gas.

16. The method recited in claim ii, wherein pivotally mounting the plurality of photovoltaic modules to the pole at the plurality of elevations comprises mounting the plurality of photovoltaic modules to the pole with a separation between the photovoltaic modules along the pole that minimizes obstruction of solar radiation on the plurality of photovoltaic device in the plurality of photovoltaic modules.

17. The method recited in claim ii, wherein the method further comprises reflecting at least some solar radiation on the plurality of photovoltaic devices mounted in the housing.

18. The method recited in claim 17, wherein reflecting at least some solar radiation on the plurality of photovoltaic devices comprises reflecting solar radiation from a plurality of surfaces within the housing upon the plurality of photovoltaic devices mounted in the housing.

19. The method recited in claim 18, wherein reflecting solar radiation from a plurality of surfaces comprises reflecting a ray of solar radiation in substantially a single plane.

20. The method recited in claim 18, wherein reflecting solar radiation from a plurality of surfaces comprises reflecting a ray of solar energy in multiple planes.

21-57. (canceled)
